(19) United States
(12) Patent Application Publication
(10) Pub. No.: US 2020/0234933 A1
(43) Pub. Date: Jul. 23, 2020

(54) GAS SUPPLY DEVICE

(71) Applicant: TOSHIBA MEMORY CORPORATION, Minato-ku (JP)

(72) Inventor: Daiki IINO, Yokohama (JP)

(73) Assignee: TOSHIBA MEMORY CORPORATION, Minato-ku (JP)

(21) Appl. No.: 16/424,577

(22) Filed: May 29, 2019

(30) Foreign Application Priority Data
Jan. 18, 2019 (JP) 2019-006794

(51) Int. Cl. H01J 37/32; H01L 21/67

(52) U.S. Cl. CPC H01J 37/32862; H01L 21/67069; H01J 2237/3341; H01J 2237/002; H01J 37/32449

(57) ABSTRACT

A gas supply device according to an embodiment comprises a first gas supplier connected to a process chamber processing a substrate, and incorporating therein first and second electrodes each generating a process gas to be supplied to the process chamber. A first pipe is interposed between the first electrode and the process chamber. A second pipe is interposed between the first electrode and a discharging part. A third pipe is interposed between the second electrode and the process chamber. A fourth pipe is interposed between the second electrode and the discharging part. A second gas supplier is connectable to the second and fourth pipes.

### CROSS REFERENCE TO RELATED APPLICATIONS

This application is based upon and claims the benefit of priority from the prior Japanese Patent Application No. 2019-006794, filed on Jan. 18, 2019, the entire contents of which are incorporated herein by reference.

### FIELD

The embodiments of the present invention relate to a gas supply device.

### BACKGROUND

There has been proposed a technique of installing a gas synthesizing device for obtaining a process gas in a device to be used in a semiconductor manufacturing process or the like. The gas synthesizing device generates a desired process gas using plasma and supplies the process gas to a process chamber.

However, the amount of the desired process gas generated in the gas synthesizing device is relatively small. Further, there is a risk that deposited materials other than process gas components adhere to pipes and clog the pipes. In this case, there is an instance where the pressure in the gas synthesizing device cannot be controlled. If the pipes are cleaned to remove the deposited materials, the process gas cannot be supplied during the cleaning.

### BRIEF DESCRIPTION OF THE DRAWINGS

FIG. 1 is a block diagram illustrating an example of a configuration of a semiconductor manufacturing device according to a first embodiment; and

FIG. 2 is a table illustrating the operations of the electrodes and the valves.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A gas supply device according to an embodiment comprises a first gas supplier connected to a process chamber processing a substrate, and incorporating therein first and second electrodes each generating a process gas to be supplied to the process chamber. A first pipe is interposed between the first electrode and the process chamber. A second pipe is interposed between the first electrode and a discharging part. A third pipe is interposed between the second electrode and the process chamber. A fourth pipe is interposed between the second electrode and the discharging part. A second gas supplier is connectable to the second and fourth pipes.

### First Embodiment

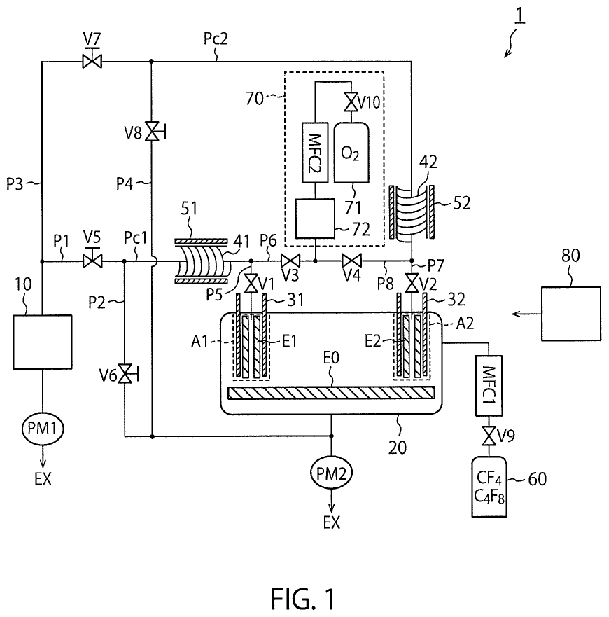

FIG. 1 is a block diagram illustrating an example of a configuration of a semiconductor manufacturing device 1 (hereinafter, also simply “device 1”) according to a first embodiment. The semiconductor manufacturing device according to the embodiment described below can be a device that processes a semiconductor substrate using a process gas, such as an etching device or a deposition device. The following explanations are provided assuming that the semiconductor manufacturing device is an etching device that performs RIE (Reactive Ion Etching).

The device 1 includes a process chamber 10, a gas supply chamber 20, electrodes E0 to E2, heaters 31, 32, 51, and 52, cooling devices 41 and 42, a source gas cylinder 60, a cleaning mechanism 70, mass flow controllers MFC1 and MFC2, valves V1 to V10, pumps PM1 and PM2, pipes P1 to P8, Pc1, and Pc2, and a controller 80. The process chamber 10 and a gas supply system other than the process chamber 10 can be constituted as one etching device or can be constituted as separate devices. Accordingly, the gas supply system can be constituted as a gas supply device separate from the process chamber 10. In this case, the gas supply device is constituted to be externally attachable to the process chamber 10.

The process chamber 10 can accommodate therein a semiconductor substrate (not illustrated) as a subject for etching processing and performs etching processing of the semiconductor substrate using an etching gas introduced from the gas supply chamber 20. When a silicon dioxide film is to be etched, the etching gas as a process gas contains at least one of CF-based gases such as CF₄, C₂F₂, C₂F₄, C₂F₆, C₃F₅, C₄F₆, and C₄F₈, as a major component.

The gas supply chamber 20 as a first gas supplier receives a source gas being a raw material of the etching gas from the source gas cylinder 60 as a third gas supplier, and generates the etching gas to be supplied to the process chamber 10. The source gas is, for example, CF₄ or C₄F₈.

The gas supply chamber 20 internally has the reference electrode E0, the first electrode E1, and the second electrode E2. The reference electrode E0 is set as, for example, a ground voltage and a high voltage can be applied to the first and second electrodes E1 and E2. Accordingly, plasma can be generated by applying an electric field between the first electrode E1 and the reference electrode E0 or between the second electrode E2 and the reference electrode E0. The source gas is dissociated or associated with the plasma to generate a desired etching gas. The desired etching gas is, for example, C₂F₂ or C₂F₄. The source gas cylinder 60 is connected to the gas supply camber 20 via the valve V9 and the mass flow controller MFC1 and supplies the source gas to the gas supply chamber 20.

An area on the first electrode E1 where the process gas is generated is a first gas generation site A1 and an area on the second electrode E2 where the process gas is generated is a second gas generation site A2.

The heater 31 as a first heater is provided around the first electrode E1 and the pipe P5 and can heat the first electrode E1 and the pipe P5 to a temperature higher than the condensation point of an impurity gas. The pipe P5 is connected to the first gas generation site A1 via the valve V1 and sends the process gas to the first common pipe Pc1. By heating the first electrode E1 and the pipe P5, the impurity gas is suppressed from depositing on the first electrode E1 and the pipe P5 arranged on an upstream side of the first common pipe Pc1 (nearer the gas supply chamber 20). The impurity gas is caused to deposit and be trapped in a portion of the first common pipe Pc1 where the cooling device 41 is arranged.

The heater 32 as a second heater is provided around the second electrode E2 and the pipe P7 and can heat the second electrode E2 and the pipe P7 to a temperature higher than the condensation point of the impurity gas. The pipe P7 is connected to the second gas generation site A2 via the valve V2 and sends the process gas to the second common pipe Pc2. By heating the second electrode E2 and the pipe P7, the impurity gas is suppressed from depositing on the second electrode E2 and the pipe P7 arranged on an upstream side of the second common pipe Pc2 (nearer the gas supply chamber 20). The impurity gas is caused to deposit and be trapped in a portion of the second common pipe Pc2 where the cooling device 42 is arranged. The heaters 31 and 32 can be, for example, heating wires.

In this case, it suffices to provide heating wires in proximity to the peripheries of the electrodes E1 and E2 or the pipes P5 and P7 or to wind the heating wires around the electrodes E1 and E2 or the pipes P5 and P7 in a coil manner, respectively. Alternatively, the heaters 31 and 32 can be pipes that enable a heated medium (oil, for example) to flow therein. In this case, it suffices to provide these pipes in proximity to the peripheries of the electrodes E1 and E2 or the pipes P5 and P7 or to wind the pipes around the electrodes E1 and E2 or the pipes P5 and P7 in a coil manner, respectively.

The cleaning mechanism 70 as a second gas supplier generates a cleaning gas to remove impurities trapped in the first and second common pipes Pc1 and Pc2. For this purpose, the cleaning mechanism 70 includes a gas cylinder 71 that holds the cleaning gas as a gas holder, and an activation device 72 that activates the cleaning gas. The gas cylinder 71 and the activation device 72 are connected with a pipe and the gas cylinder 71 supplies the cleaning gas via the valve V10 and the mass flow controller MFC2 to the activation device 72. The cleaning gas is, for example, oxygen. The activation device 72 activates the cleaning gas. The activation device 72 activates, for example, oxygen using plasma to generate oxygen radicals (O*). The cleaning mechanism 70 is connected to both the first common pipe Pd. and the second common pipe Pc2. Therefore, the activated cleaning gas (oxygen radicals) can be supplied to the first common pipe Pc1 via the pipe P6 or can be supplied to the second common pipe Pc2 via the pipe P8. Accordingly, the cleaning mechanism 70 removes the impurities trapped in the first common pipe Pc1 or removes the impurities trapped in the second common pipe Pc2. The cleaning gas and the impurity gas are discharged from the pump PM2. In this way, the cleaning mechanism 70 can clean the first and second common pipes Pc1 and Pc2.

The process chamber 10 is connected to the pump PM1 and the etching gas after use is discharged from the pump PM1.

### (First Gas Supply System)

The process chamber 10 is connected to the first common pipe Pc1 via the pipe P1 as a first pipe. The pipe P1 is interposed between the first electrode E1 and the process chamber 10 and sends the etching gas from the first electrode E1 to the process chamber 10. The valve V5 as a fifth valve is provided on the pipe P1 to be capable of opening and closing the pipe P1.

The first common pipe Pc1 is coupled to the first electrode E1 in the gas supply chamber 20 via the valve V1 as a first valve. The valve V1 is provided on the pipe P5 arranged between the first gas generation site A1 (the first electrode E1) and the first common pipe Pc1 of a first gas supply system. The cooling device 41 is provided on an outer periphery of the first common pipe Pc1 and can cool the first common pipe Pc1. The cooling device 41 can be, for example, a Peltier device. Alternatively, the cooling device 41 can be a pipe wound around the first common pipe Pc1 in a coil manner and enabling a cooling medium such as liquid nitrogen or liquid helium to flow therethrough. Accordingly, the cooling device 41 can cool and condense impurity components contained in the etching gas flowing in the first common pipe Pc1 to be trapped in the first common pipe Pc1. The impurity components are, for example, radicals of C₄F₈ being an undissociated source gas or CF, CF₂, CF₃, or the like formed by dissociating a source gas, and have a condensation point higher than that of the etching gas (C₂F₂ or C₂F₄, for example). The cooling device 41 controls the first common pipe Pc1 to a temperature higher than the condensation point of the etching gas and lower than the condensation point of the impurity components. Accordingly, the impurity components can be selectively condensed (liquefied) in the first common pipe Pc1, or solidified to be trapped in the first common pipe Pc1. At this time, the etching gas from which the impurity components have been removed passes through the first common pipe Pc1 as it is as a gas and is supplied to the process chamber 10 via the first pipe P1. In this way, the first gas supply system has the pipes P5, Pc1, and P1, and the first electrode E1 and the process chamber 10 are connected with the pipes P5, Pc1, and P1.

For example, when C₂F₄ is used as the etching gas, the boiling point of C₂F₄ is about −76° C. and the flash point thereof is about 187° C. Therefore, it is preferable that the heaters 31 and 51 and the cooling device 41 control the temperatures of the first common pipe Pc1 and the first electrode E1 (the temperature of the etching gas) between about −76° C. and about 187° C. In order to trap an impurity gas by the cooling device 41 at the time of supply the etching gas, the cooling device 41 cools the first common pipe Pc1 to cause the temperature of the first common pipe Pc1 to be lower than the condensation point of the impurity components. Meanwhile, in order to prevent the impurity gas from depositing on the first electrode E1 and the pipe P5, the heater 31 heats the first electrode E1 to cause the temperature of the first electrode E1 to be higher than the condensation point of the impurity components.

The heater 51 as a third heater is also provided outside the portion of the first common pipe Pc1 where the cooling device 41 is arranged. The heater 51 can heat the first common pipe Pc1 to a temperature higher than the condensation point of the impurities. The heater 51 can heat the first common pipe Pc1 at the time of cleaning to gasify the trapped impurities. The heater 51 also enables the activated cleaning gas supplied from the cleaning mechanism 70 to react with the trapped impurities to promote decomposition of the impurities. A gasified or decomposed impurity gas can be discharged from the pump PM2 via the pipe P2.

The heater 51 can have an identical configuration to that of the heater 31. That is, the heater 51 can be, for example, a heating wire. In this case, it suffices to provide the heating wire in proximity to the periphery of the first common pipe Pc1 or the cooling device 41 or to wind the heating wire around the first common pipe Pc1 or the cooling device 41 in a coil manner. Alternatively, the heater 51 can be a pipe that enables a heated medium (oil, for example) to flow therethrough. In this case, it suffices to provide the pipe in proximity to the periphery of the first common pipe Pc1 or the cooling device 41 or to wind the pipe around the first common pipe Pc1 or the cooling device 41 in a coil manner.

An end of the first common pipe Pc1 is connected to the pipes P1 and P2. The pipe P1 is connected to the process chamber 10 and sends the process gas to the process chamber 10. The pipe P2 as a second pipe is connected between the first common pipe Pc1 and the pump PM2 and is interposed between the first electrode E1 and a discharging part EX. The valve V6 as a sixth valve is provided on the pipe P2 to be capable of opening and closing the pipe P2. The pump PM2 can discharge the impurity components trapped in the first common pipe Pc1 via the pipe P2. As described above, the pipe P2 and the valve V6 are connected to the first common pipe Pc1 of the first gas supply system and function as a first discharging site that discharges the impurity components, the cleaning gas, and a redundant part of the process gas.

The other end of the first common pipe Pc1 is coupled to the first electrode E1 via the pipe P5 and is also connected to the cleaning mechanism 70 via the pipe P6. The valve V1 is provided on the pipe P5 to be capable of opening and closing the pipe P5. The valve V3 as a third valve is provided on the pipe P6 to be capable of opening and closing the pipe P6. That is, the valve V3 is provided on the pipe P6 arranged between the cleaning mechanism 70 and the first common pipe Pc1 of the first gas supply system. The etching gas generated by the first electrode E1 is sent to the first common pipe Pc1 via the pipe P5. The cleaning gas generated by the cleaning mechanism 70 is sent to the first common pipe Pc1 via the pipe P6.

### (Second Gas Supply System)

Meanwhile, the process chamber 10 is connected also to the second common pipe Pc2 via the pipe P3 as a third pipe. The pipe P3 is interposed between the second electrode E2 and the process chamber 10 and sends the etching gas from the second electrode E2 to the process chamber 10. The valve V7 as a seventh valve is provided on the pipe P3 to be capable of opening and closing the pipe P3.

The second common pipe Pc2 is coupled to the second electrode E2 in the gas supply chamber 20 via the valve V2 as a second valve. The valve V2 is provided on the pipe P7 arranged between the second gas generation site A2 (the second electrode E2) and the second common pipe Pc2 of a second gas supply system. The cooling device 42 is provided on the outer periphery of the second common pipe Pc2 and can cool the second common pipe Pc2. The cooling device 42 can be, for example, a Peltier device or can be a pipe wound around the second common pipe Pc2 in a coil manner to enable a cooling medium to flow therethrough, similarly to the cooling device 41. The cooling device 42 controls the second common pipe Pc2 to a temperature higher than the condensation point of the etching gas and lower than the condensation point of the impurity components. Accordingly, the cooling device 42 can cool and condense or solidify the impurity components contained in the etching gas flowing in the second common pipe Pc2 to be trapped in the second common pipe Pc2. At this time, the etching gas from which the impurity components have been removed passes through the second common pipe Pc2 as it is as a gas and is supplied to the process chamber 10 via the third pipe P3. In this way, the second gas supply system has the pipes P7, Pc2, and P3, and the second electrode E2 and the process chamber 10 are connected with the pipes P7, Pc2, and P3.

For example, when C₂F₄ is used as the etching gas as described above, it is preferable that the heaters 32 and 52 and the cooling device 42 control the temperatures of the second common pipe Pc2 and the second electrode E2 (the temperature of the etching gas) between about −76° C. and about 187° C. In order to trap the impurity gas by the cooling device 42 at the time of supply of the etching gas, the cooling device 42 cools the second common pipe Pc2 to cause the temperature of the second common pipe Pc2 to be lower than the condensation point of the impurity components. Meanwhile, in order to prevent the impurity gas from depositing on the second electrode E2 and the pipe P7, the heater 32 heats the second electrode E2 to cause the temperature of the second electrode E2 to be higher than the condensation point of the impurity components.

The heater 52 as a fourth heater is provided outside the portion of the second common pipe Pc2 where the cooling device 42 is arranged. The heater 52 can heat the second common pipe Pc2 to a temperature higher than the condensation point of the impurities. The heater 52 can heat the second common pipe Pc2 at the time of cleaning to gasify the trapped impurities. The heater 52 also enables the activated cleaning gas supplied from the cleaning mechanism 70 to react with the trapped impurities to promote decomposition of the impurities. A gasified or decomposed impurity gas can be discharged from the pump PM2 via the pipe P4.

The heater 52 can have an identical configuration to that of the heater 32. That is, the heater 52 can be, for example, a heating wire. In this case, it suffices to provide the heating wire in proximity to the periphery of the second common pipe Pc2 or the cooling device 42 or to wind the heating wire around the second common pipe Pc2 or the cooling device 42 in a coil manner. The heater 52 can be a pipe that enables a heated medium (oil, for example) to flow therethrough. In this case, it suffices to provide the pipe in proximity to the periphery of the second common pipe Pc2 or the cooling device 42 or to wind the pipe around the second common pipe Pc2 or the cooling device 42 in a coil manner.

An end of the second common pipe Pc2 is connected to the pipes P3 and P4. The pipe P3 is connected to the process chamber 10 and sends the process gas to the process chamber 10. The pipe P4 as a fourth pipe is connected between the second common pipe Pc2 and the pump PM2 and is interposed between the second electrode E2 and the discharging part EX. The valve V8 as an eighth valve is provided on the pipe P4 to be capable of opening and closing the pipe P4. The pump PM2 can discharge the impurity components trapped in the second common pipe Pc2 via the pipe P4. As described above, the pipe P4 and the valve V8 are connected to the second common pipe Pc2 of the second gas supply system and function as a second discharging site that discharges the impurity components, the cleaning gas, and a redundant part of the process gas.

The other end of the second common pipe Pc2 is coupled to the second electrode E2 via the pipe P7 and is also connected to the cleaning mechanism 70 via the pipe P8. The valve V2 is provided on the pipe P7 to be capable of opening and closing the pipe P7. The valve V4 as a fourth valve is provided on the pipe P8 to be capable of opening and closing the pipe P8. That is, the valve V4 is provided on the pipe P8 arranged between the cleaning mechanism 70 and the second common pipe Pc2 of the second gas supply system. The etching gas generated by the second electrode E2 is sent to the second common pipe Pc2 via the pipe P7. The cleaning gas generated by the cleaning mechanism 70 is sent to the second common pipe Pc2 via the pipe P8.

With the configuration described above, the first gas supply system supplies an etching gas from the first electrode E1 to the process chamber 10 via the pipe P5, the first common pipe Pc1, the pipe P1, and the like. The second gas supply system supplies an etching gas from the second electrode E2 to the process chamber 10 via the pipe P7, the second common pipe Pc2, the pipe P3, and the like. Accordingly, the etching gases from the first and second electrodes E1 and E2 can be supplied to the process chamber 10 via separate first and second gas supply systems, respectively.

Further, the cleaning mechanism 70 can be connected to the first common pipe Pc1 via the pipe P6 of the first gas supply system and the first gas supply system can remove and discharge an impurity gas from the first common pipe Pc1 via the pipe P2. The cleaning mechanism 70 can also be connected to the second common pipe Pc2 via the pipe P8 of the second gas supply system and the second gas supply system can remove and discharge an impurity gas from the second common pipe Pc2 via the pipe P4. Accordingly, the common single cleaning mechanism 70 can remove impurities trapped in both the first and second common pipes Pc1 and Pc2.

The controller 80 controls the constituent parts of the semiconductor manufacturing device 1. For example, when the etching gas from the first electrode E1 is to be supplied to the process chamber 10, the controller 80 opens the valves V1 and V5 and closes the valves V3 and V7. The valve V6 can be open to adjust the supply amount of the etching gas. The etching gas from the first electrode E1 is supplied to the process chamber 10 via the pipes P5, Pc1, and P1. At this time, the controller 80 drives the cooling device 41 to cool the first common pipe Pc1 and condense impurities contained in the etching gas to be trapped in the first common pipe Pc1. At the same time, the controller 80 drives the heater 31 to heat the first electrode E1 and the pipe P5 to prevent the impurities from depositing on the first electrode E1 and the pipe P5. The heater 51 is in a standby state without being driven. The valves V9 and V10 are kept in an open state.

Meanwhile, at this time, the second electrode E2 generates no etching gas and the cleaning mechanism 70 cleans the second common pipe Pc2. Therefore, the controller 80 opens the valves V4 and V8 and closes the valve V2. The cleaning gas from the cleaning mechanism 70 is discharged from the pump PM2 via the pipes P8, Pc2, and P4. At this time, the controller 80 drives the heater 52 to heat the second common pipe Pc2 and gasify or decompose impurities trapped in the second common pipe Pc2. A gasified or decomposed impurity gas is discharged with the cleaning gas from the pump PM2 via the second common pipe Pc2 and the pipe P4. At this time, the cooling device 42 and the heater 32 are in a standby state without being driven.

On the contrary, when the etching gas from the second electrode E2 is to be supplied to the process chamber 10, the controller 80 opens the valves V2 and V7 and closes the valves V4 and V5. The valve V8 can be open to adjust the supply amount of the etching gas. The etching gas from the second electrode E2 is supplied to the process chamber 10 via the pipes P7, Pc2, and P3. At this time, the controller 80 drives the cooling device 42 to cool the second common pipe Pc2 and condense impurities contained in the etching gas to be trapped in the second common pipe Pc2. At the same time, the controller 80 drives the heater 32 to heat the second electrode E2 and the pipe P7 to prevent the impurities from depositing on the second electrode E2 and the pipe P7. The heater 52 is in a standby state without being driven.

Meanwhile, at this time, the first electrode E1 generates no etching gas and the cleaning mechanism 70 cleans the first common pipe Pc1. Therefore, the controller 80 opens the valves V3 and V6 and the closes the valve V1. The cleaning gas from the cleaning mechanism 70 is discharged from the pump PM2 via the pipes P6, Pc1, and P2. At this time, the controller 80 drives the heater 51 to heat the first common pipe Pc1 to gasify or decompose impurities trapped in the first common pipe Pc1. A gasified or decomposed impurity gas is discharged with the cleaning gas from the pump PM2 via the first common pipe Pc1 and the pipe P2. At this time, the cooling device 41 and the heater 31 are in a standby state without being driven.

As described above, the semiconductor manufacturing device 1 according to the present embodiment can supply the cleaning gas from the cleaning mechanism 70 to the second common pipe Pc2 of the second gas supply system and clean the second common pipe Pc2 of the second gas supply system while supplying an etching gas from the first electrode E1 to the process chamber 10 using the first gas supply system (Step 1). On the contrary, the semiconductor manufacturing device 1 can supply the cleaning gas from the cleaning mechanism 70 to the first common pipe Pc1 of the first gas supply system and clean the first common pipe Pc1 of the first gas supply system while supplying an etching gas from the second electrode E2 to the processing chamber 10 using the second gas supply system (Step 2). The semiconductor manufacturing device 1 periodically repeats Step 1 and Step 2. Accordingly, the semiconductor manufacturing device 1 can trap impurities while continuously supplying an etching gas in a certain period and remove the trapped impurities in the next period. As a result, pipe clogging due to deposition of impurities can be suppressed and an etching gas can be stably supplied.

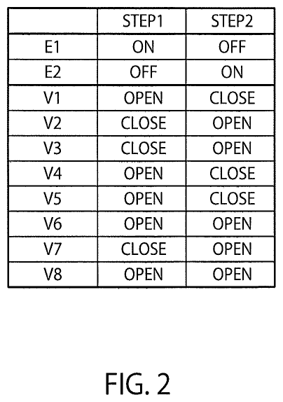

FIG. 2 is a table illustrating the operations of the electrodes E1 and E2 and the valves V1 to V8. For example, at Step 1, the first electrode E1 is in an on-state and generates an etching gas in the first gas generation site A1. At this time, the second electrode E2 is in an off-state and the second common pipe Pc2 of the second gas supply system is cleaned. Therefore, the controller 80 opens the valves V1, V4, V5, V6, and V8 and closes other valves V2, V3, and V7. Accordingly, the etching gas from the first electrode E1 is supplied to the process chamber 10 via the pipe P5, the first common pipe Pc1, and the pipe P1. At this time, the first common pipe Pc1 is cooled by the first cooling device 41 and traps impurities. Meanwhile, the cleaning gas from the cleaning mechanism 70 cleans the pipe P8, the second common pipe Pc2, and the pipe P4 and is discharged from the pump PM2.

At Step 2, the second electrode E2 is in an on-state and generates an etching gas in the second gas generation site A2. At this time, the first electrode E1 is in an off-state and the first common pipe Pc1 of the first gas supply system is cleaned. Therefore, the controller 80 opens the valves V2, V3, V6, V7, and V8 and closes other valves V1, V4, and V5. Accordingly, the etching gas from the second electrode E2 is supplied to the process chamber 10 via the pipe P7, the second common pipe Pc2, and the pipe P3. At this time, the second common pipe Pc2 is cooled by the second cooling device 42 and traps impurities. Meanwhile, the cleaning gas from the cleaning mechanism 70 cleans the pipe P6, the first common pipe Pc1, and the pipe P2 and is discharged from the pump PM2.

According to the present embodiment, an etching gas is continuously supplied to the process chamber 10 by alternately repeating Step 1 and Step 2. Therefore, the supply amount of the etching gas can be increased. The first and second cooling devices 41 and 42 are alternately and periodically cleaned. Therefore, clogging of pipes is unlikely to occur.

The supply systems and the discharge systems including the common pipes Pc1 and Pc2, the pipes P1 and P3, the pipes P2 and P4, the cooling devices 41 and 42, the heaters 31 and 32, and the heaters 51 and 52 are respectively provided as many as the electrodes E1 and E2. Therefore, in the present embodiment, two supply systems and two discharge systems are provided to correspond to the two electrodes E1 and E2, respectively. However, the number of electrodes can be three or more. In this case, it suffices to respectively provide the supply systems and the discharge systems as many as the electrodes.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A gas supply device comprising:
a first gas supplier connected to a process chamber processing a substrate, the first gas supplier incorporating therein first and second electrodes respectively generating a process gas which is supplied to the process chamber;
a first pipe interposed between the first electrode and the process chamber;
a second pipe interposed between the first electrode and a discharging part;
a third pipe interposed between the second electrode and the process chamber;
a fourth pipe interposed between the second electrode and the discharging part; and
a second gas supplier connectable to the second and fourth pipes.

2. The device of claim 1, further comprising:
a first common pipe having one end connected to the first and second pipes and another end coupled to the first electrode;
a first cooling device arranged on the first common pipe;
a second common pipe having one end connected to the third and fourth pipes and another end coupled to the second electrode; and
a second cooling device arranged on the second common pipe.

3. The device of claim 2, further comprising:
a first heater arranged on the first electrode; and
a second heater arranged on the second electrode.

4. The device of claim 3, further comprising:
a third heater arranged on the first cooling device or the first common pipe; and
a fourth heater arranged on the second cooling device or the second common pipe.

5. The device of claim 2, wherein the second gas supplier comprises a gas holder supplying a cleaning gas and an activation device activating the cleaning gas, and
the second gas supplier is connected in common to the first common pipe and the second common pipe.

6. The device of claim 5, wherein the cleaning gas is oxygen.

7. The device of claim 1, further comprising a third gas supplier connected to the first gas supplier and supplying a source gas being a raw material of the process gas to the first gas supplier.

8. The device of claim 1, further comprising:
a first common pipe having one end connected to the first and second pipes and another end coupled to the first electrode; and
a second common pipe having one end connected to the third and fourth pipes and another end coupled to the second electrode, wherein
the second gas supplier is connected to the discharging part via the first common pipe and the second pipe and via the second common pipe and the fourth pipe.

9. The device of claim 1, comprising:
a first common pipe having one end connected to the first and second pipes;
a second common pipe having one end connected to the third and fourth pipes;
a first valve arranged between the first electrode and the first common pipe;
a second valve arranged between the second electrode and the second common pipe;
a third valve arranged between the second gas supplier and the first common pipe;
a fourth valve arranged between the second gas supplier and the second common pipe;
a fifth valve arranged on the first pipe;
a sixth valve arranged on the second pipe;
a seventh valve arranged on the third pipe; and
an eighth valve arranged on the fourth pipe.

10. The device of claim 8, wherein
the second gas supplier causes a cleaning gas to flow via the second common pipe and the fourth pipe when the process gas is supplied from the first electrode to the process chamber via the first common pipe and the first pipe, and
the second gas supplier causes the cleaning gas to flow via the first common pipe and the second pipe when the process gas is supplied from the second electrode to the process chamber via the second common pipe and the third pipe.

11. The device of claim 9, wherein
the first and fifth vales are opened when the process gas is supplied from the first electrode to the process chamber,
the fourth and eight valves are opened when a cleaning gas is caused to flow from the second gas supplier to the second common pipe and the fourth pipe,
the second and seventh valves are opened when the process gas is supplied from the second electrode to the process chamber, and
the third and sixth valves are opened when the cleaning gas is caused to flow from the second gas supplier to the first common pipe and the second pipe.

12. The device of claim 4, wherein
a major component of the process gas is C₂F₄, and
the first and second cooling devices and the first to fourth heaters control temperatures of the first and second common pipes and the first and second electrodes in a range between −76° C. to 187° C.

13. The device of claim 4, wherein the first and second cooling devices control temperatures of the first and second common pipes in a temperature range higher than a condensation point of the process gas and lower than a condensation point of impurity components except the process gas.

14. The device of claim 13, wherein the first to fourth heaters control temperatures of the first and second common pipes and the first and second electrodes to a temperature higher than the condensation point of the impurity components.

15. A gas supply device comprising:
a gas supplier being capable of generating a process gas to be supplied to a process chamber processing a substrate, and comprising a first gas generation site generating the process gas using a first electrode and a second gas generation site generating the process gas using a second electrode;
a discharging system comprising a first discharging site connected to a first path between the first gas generation site and the process chamber, and a second discharging site connected to a second path between the second gas generation site and the process chamber; and
a cleaning mechanism supplying a cleaning gas removing impurities deposited in the first and second paths, wherein
the second path is blocked at a downstream side of the second discharging site and the cleaning mechanism is connected to the second path at an upstream side of the second discharging site when the process gas is supplied to the process chamber through the first path, and
the first path is blocked at a downstream side of the first discharging site and the cleaning mechanism is connected to the first path at an upstream side of the first discharging site when the process gas is supplied to the process chamber through the second path.

16. The device of claim 15, wherein
the cleaning mechanism supplies the cleaning gas to the second path when the process gas is supplied to the process chamber through the first path, and
the cleaning mechanism supplies the cleaning gas to the first path when the process gas is supplied to the process chamber through the second path.

17. The device of claim 15, wherein
the first path is cooled to trap the impurities in the first path when the process gas is supplied to the process chamber through the first path, and
the second path is cooled to trap the impurities in the second path when the process gas is supplied to the process chamber through the second path.

18. The device of claim 15, wherein
the second path is heated to discharge the impurities trapped in the second path to the second discharging site when the process gas is supplied to the process chamber through the first path, and
the first path is heated to discharge the impurities trapped in the first path to the first discharging site when the process gas is supplied to the process chamber through the second path.

19. The device of claim 15, wherein the cleaning mechanism comprises a gas holder supplying the cleaning gas, and an activation device activating the cleaning gas.

20. The device of claim 19, wherein the cleaning gas is oxygen.
